(19) United States
(12) Patent Application Publication
(10) Pub. No.: US 2026/0331183 A1
(43) Pub. Date: Oct. 22, 2026

(54) SEMICONDUCTOR DEVICE AND METHOD OF MANUFACTURTING THEREOF, METHOD OF OPERATING THEREOF, SEMICONDUCTOR STRUCTURE, PACKAGE STRUCTURE, AND COMPUTING-IN-MEMORY DEVICE

(71) Applicant: Yangtze Memory Technologies Holding Co., Ltd., Wuhan (CN)

(72) Inventors: Zongliang Huo, Wuhan (CN); Yu Zhang, Wuhan (CN); Lei Jin, Wuhan (CN); Weihua Shi, Wuhan (CN); Feng Xu, Wuhan (CN); Da Li, Wuhan (CN)

(73) Assignee: Yangtze Memory Technologies Holding Co., Ltd., Wuhan (CN)

(21) Appl. No.: 19/406,647

(22) Filed: Dec. 2, 2025

(30) Foreign Application Priority Data
Apr. 18, 2025 (CN) 202510494756.4

(51) Int. Cl. G11C 16/26; G11C 16/34; H10B 80/00; H10D 80/30; H10W 90/00

(52) U.S. Cl. CPC G11C 16/26; G11C 16/3459; H10B 80/00; H10D 80/30; H10W 90/792

(57) ABSTRACT

Some examples of the present disclosure provide a semiconductor device. The semiconductor device comprises first and second semiconductor structures bonded to each other. The first semiconductor structure includes a memory array, a peripheral circuit coupled to the memory array, and a first bonding contact, a second bonding contact and a third bonding contact respectively coupled to the peripheral circuit, and the second semiconductor structure comprises a control circuit, an analog-to-digital conversion circuit coupled to the control circuit, a fourth bonding contact and a fifth bonding contact respectively coupled to the control circuit, and a sixth bonding contact coupled to the analog-to-digital conversion circuit. Various channels are formed between different bonding contacts to transmit different information.

### CROSS-REFERENCE TO RELATED APPLICATIONS

This application claims the benefit of priority to Chinese Application No. 202510494756.4, filed on Apr. 18, 2025, which is hereby incorporated by reference in its entirety.

### FIELD OF TECHNOLOGY

The present disclosure relates to, but is not limited to, a semiconductor device and a method of manufacturing thereof, a method of operating thereof, a semiconductor structure, a package structure, and a computing-in-memory device.

### BACKGROUND

In the classical Von Neumann's computing architecture, the memory and processor are separated, and data is transmitted between them through a data bus. When executing commands, the processor first reads data from the memory, processes it, and then writes the updated data back to the memory. Frequent data migration brings huge power consumption and time overhead; in addition, due to the limited bandwidth of the memory, the processing speed of the processor is limited by the access speed of the memory, which greatly affects the computing performance. With the rise of applications such as big data and artificial intelligence, the processing of massive amounts of data has made the bottleneck of Von Neumann's computing architecture increasingly prominent.

### SUMMARY

In view of this, examples of the present disclosure provide a semiconductor device and a method of manufacturing thereof, a method of operating thereof, a semiconductor structure, a package structure, and a computing-in-memory device.

According to a first aspect, an example of the present disclosure provides a semiconductor device, including a first semiconductor structure and a second semiconductor structure bonded to each other, where the first semiconductor structure includes a memory array, a peripheral circuit coupled to the memory array, and a first bonding contact, a second bonding contact and a third bonding contact respectively coupled to the peripheral circuit, the second semiconductor structure includes a control circuit, an analog-to-digital conversion circuit coupled to the control circuit, a fourth bonding contact and a fifth bonding contact respectively coupled to the control circuit, and a sixth bonding contact coupled to the analog-to-digital conversion circuit, where a first signal channel is formed between the first bonding contact and the fourth bonding contact, a second signal channel is formed between the second bonding contact and the fifth bonding contact, a third signal channel is formed between the third bonding contact and the sixth bonding contact, and the first signal channel, the second signal channel, and the third signal channel are configured to transmit different information.

In some examples, the first signal channel is configured to transmit system information adapted to an ONFI protocol and system information between the control circuit and the peripheral circuit in performing a computing-in-memory process, the second signal channel is configured to transmit synchronization control information between the peripheral circuit and the control circuit in performing the computing-in-memory process, and the third signal channel is configured to transmit system information between the memory array and the analog-to-digital conversion circuit in performing the computing-in-memory process.

In some examples, when performing a first read operation, the control circuit is configured to send a first command through the first signal channel, the peripheral circuit is configured to: in response to the first command, send first synchronization control information through the second signal channel, where the first synchronization control information includes a trigger signal for the first read operation to start sensing, the control circuit is configured to: send a first control signal to the analog-to-digital conversion circuit, the analog-to-digital conversion circuit is configured to: in response to the first control signal, obtain a first computing-in-memory current signal output by the memory array through the third signal channel; and convert the first computing-in-memory current signal into first read data, the control circuit is configured to: send second synchronization control information through the second signal channel, where the second synchronization control information includes a trigger signal for sensing completion of the first read operation, and the peripheral circuit is configured to: send third synchronization control information through the second signal channel, where the third synchronization control information includes an end signal for the first read operation.

In some examples, in a first period, the first command is transmitted through the first signal channel, in a second period, the first synchronization control information is transmitted through the second signal channel, and the first computing-in-memory current signal is transmitted through the third signal channel, where the first period is earlier than the second period, in a third period, the second synchronization control information is transmitted through the second signal channel, where the second period is earlier than the third period, and in a fourth period, the third synchronization control information is transmitted through the second signal channel, where the third period is earlier than the fourth period.

In some examples, when performing a write operation, the control circuit is configured to: send a second command through the first signal channel, where the second command includes write data, and the peripheral circuit is configured to: in response to the second command, store the write data to the memory array.

In some examples, when performing a write verification operation, the peripheral circuit is configured to: send fourth synchronization control information through the second signal channel, where the fourth synchronization control information includes state information of the memory array, the control circuit is configured to: send a second control signal to the analog-to-digital conversion circuit, the analog-to-digital conversion circuit is configured to: in response to the second control signal, obtain a second computing-in-memory current signal output by the memory array through the third signal channel; and convert the second computing-in-memory current signal into verification data, the control circuit is configured to: verify with the write data and the verification data, and send fifth synchronization control information through the second signal channel, where the fifth synchronization control information includes a completion signal for a verification operation, the peripheral circuit is configured to: send sixth synchronization control information through the second signal channel, where the sixth synchronization control information includes a signal for storing the verification data to the memory array, the control circuit is configured to: send a third control signal to the analog-to-digital conversion circuit, the analog-to-digital conversion circuit is configured to: in response to the third control signal, store the verification data to the memory array through the third signal channel, or the control circuit is configured to: store the verification data to the memory array through the first signal channel, and the peripheral circuit is configured to: send seventh synchronization control information through the second signal channel, where the seventh synchronization control information includes an end signal for the write operation.

In some examples, in a fifth period, the second command is transmitted through the first signal channel, in a sixth period, the fourth synchronization control information is transmitted through the second signal channel, the second computing-in-memory current signal is transmitted through the third signal channel, the fifth synchronization control information and the sixth synchronization control information are respectively transmitted through the second signal channel, the verification data is transmitted through the third signal channel or the first signal channel, the fifth period is earlier than the sixth period, and in a seventh period, the seventh synchronization control information is transmitted through the second signal channel, and the sixth period is earlier than the seventh period.

In some examples, when performing a second read operation, the control circuit is configured to: send a third command through the first signal channel, and the peripheral circuit is configured to: in response to the third command, send second read data stored in the memory array to the control circuit through the first signal channel.

In some examples, the first semiconductor structure further includes a bit line located between the peripheral circuit and the memory array, and the memory array is coupled to the peripheral circuit through the bit line.

In some examples, the first semiconductor structure includes a first sub-semiconductor structure formed with the memory array and a second sub-semiconductor structure formed with the peripheral circuit, the first sub-semiconductor structure further includes a first bonding layer and a second bonding layer located on two opposite sides of the memory array, the second sub-semiconductor structure further includes a third bonding layer formed with the first bonding contact, the second bonding contact and the third bonding contact, the second semiconductor structure includes a fourth bonding layer formed with the fourth bonding contact, the fifth bonding contact and the sixth bonding contact, the fourth bonding layer is bonded to the first bonding layer, and the second bonding layer is bonded to the third bonding layer.

In some examples, the semiconductor device further includes: a first connection structure through the memory array and connected to the first bonding contact and the fourth bonding contact respectively, a second connection structure through the memory array and connected to the second bonding contact and the fifth bonding contact respectively, and a third connection structure through the memory array and connected to the third bonding contact and the sixth bonding contact respectively.

In some examples, the second semiconductor structure includes a three-dimensional NAND type memory.

According to a second aspect, an example of the present disclosure provides a package structure, including: a package substrate, the semiconductor device according to the above examples, and a molding layer, where the semiconductor device is disposed on the package substrate, and the molding layer encapsulates the semiconductor device.

According to a third aspect, an example of the present disclosure provides a computing-in-memory device, including the semiconductor device according to the above examples.

According to a fourth aspect, an example of the present disclosure provides a semiconductor structure, including a memory array, a peripheral circuit coupled to the memory array, a first bonding contact, a second bonding contact, and a third bonding contact respectively coupled to the peripheral circuit, where the first bonding contact is configured to transmit a first signal, the second bonding contact is configured to transmit a second signal, and the third bonding contact is configured to transmit a third signal, where information contents of the first signal, the second signal, and the third signal are different.

In some examples, information content of the first signal includes system information adapted to an ONFI protocol and system information interacted with the peripheral circuit in performing a computing-in-memory process, information content of the second signal includes synchronization control information interacted with the peripheral circuit in performing the computing-in-memory process, and information content of the third signal includes system information interacted with the memory array in performing the computing-in-memory process.

In some examples, the semiconductor structure includes a first sub-semiconductor structure formed with the memory array and a second sub-semiconductor structure formed with the peripheral circuit, the first sub-semiconductor structure further includes a first bonding layer and a second bonding layer located on two opposite sides of the memory array, the second sub-semiconductor structure further includes a third bonding layer formed with the first bonding contact, the second bonding contact and the third bonding contact, and the second bonding layer is bonded to the third bonding layer.

In some examples, the semiconductor structure further includes: a first connection structure through the memory array and connected to the first bonding contact, a second connection structure through the memory array and connected to the second bonding contact, and a third connection structure through the memory array and connected to the third bonding contact.

In some examples, the semiconductor structure further includes: a bit line located between the peripheral circuit and the memory array, and the memory array is coupled to the peripheral circuit through the bit line.

According to a fifth aspect, an example of the present disclosure provides a method of manufacturing a semiconductor device, including: forming a first semiconductor structure and a second semiconductor structure bonded to each other, where the first semiconductor structure includes a memory array, a peripheral circuit coupled to the memory array, a first bonding contact, a second bonding contact and a third bonding contact respectively coupled to the peripheral circuit, the second semiconductor structure includes a control circuit, an analog-to-digital conversion circuit coupled to the control circuit, a fourth bonding contact and a fifth bonding contact respectively coupled to the control circuit, and a sixth bonding contact coupled to the analog-to-digital conversion circuit, where the first bonding contact is coupled to the fourth bonding contact to form a first signal channel, the second bonding contact is coupled to the fifth bonding contact to form a second signal channel, the third bonding contact is coupled to the sixth bonding contact to form a third signal channel, and the first signal channel, the second signal channel, and the third signal channel transmit different information.

In some examples, the first signal channel transmits system information adapted to an ONFI protocol and system information between the control circuit and the peripheral circuit in performing a computing-in-memory process, the second signal channel transmits synchronization control information between the peripheral circuit and the control circuit in performing the computing-in-memory process, and the third signal channel transmits system information between the memory array and the analog-to-digital conversion circuit in performing the computing-in-memory process.

In some examples, the method further includes: forming a bit line between the peripheral circuit and the memory array, and coupling the memory array to the peripheral circuit through the bit line.

In some examples, the forming the first semiconductor structure and the second semiconductor structure bonded to each other includes: forming the memory array, a first bonding layer and a second bonding layer on two opposite sides of the memory array to form a first sub-semiconductor structure; forming the peripheral circuit and a third bonding layer including the first bonding contact, the second bonding contact and the third bonding contact to form a second sub-semiconductor structure; forming the control circuit, the analog-to-digital conversion circuit, and a fourth bonding layer including the fourth bonding contact, the fifth bonding contact and the sixth bonding contact to form a second semiconductor structure; and bonding the fourth bonding layer to the first bonding layer and bonding the second bonding layer to the third bonding layer to form the first semiconductor structure and the second semiconductor structure bonded to each other.

In some examples, the method further includes: forming a first connection structure through the memory array and connected to the first bonding contact and the fourth bonding contact respectively; forming a second connection structure through the memory array and connected to the second bonding contact and the fifth bonding contact respectively; and forming a third connection structure through the memory array and connected to the third bonding contact and the sixth bonding contact respectively.

According to a sixth aspect, an example of the present disclosure provides a method of operating a semiconductor device, where the semiconductor device includes the semiconductor device according to the above examples of the present disclosure, the method includes: when performing a first read operation, transmitting, by the control circuit, a first command to the peripheral circuit through the first signal channel, where the first command includes a first read instruction, a first read address, and input vector data; in response to the first command, transmitting, by the peripheral circuit, first synchronization control information to the control circuit through the second signal channel, where the first synchronization control information includes a trigger signal for the first read operation to start sensing; instructing, by the control circuit, the analog-to-digital conversion circuit to obtain a first computing-in-memory current signal through the third signal channel, and convert the first computing-in-memory current signal into first read data; transmitting, by the control circuit, second synchronization control information to the peripheral circuit through the second signal channel, where the second synchronization control information includes a trigger signal for sensing completion of the first read operation; and transmitting, by the peripheral circuit, third synchronization control information through the second signal channel, where the third synchronization control information includes an end signal for the first read operation.

In some examples, the method further includes: when performing a write operation, transmitting, by the control circuit, a second command to the peripheral circuit through the first signal channel, where the second command includes write data; and in response to the second command, storing, by the peripheral circuit, the write data to the memory array.

In some examples, the method further includes: when performing a write verification operation, transmitting, by the peripheral circuit, fourth synchronization control information to the control circuit through the second signal channel, where the fourth synchronization control information includes state information of the memory array; instructing, by the control circuit, the analog-to-digital conversion circuit to obtain a second computing-in-memory current signal through the third signal channel, and convert the second computing-in-memory current signal into verification data; and verifying with the write data and the verification data; transmitting, by the control circuit, fifth synchronization control information to the peripheral circuit through the second signal channel, where the fifth synchronization control information includes a completion signal for the write verification operation; transmitting, by the peripheral circuit, sixth synchronization control information through the second signal channel, where the sixth synchronization control information includes a signal for storing the verification data to the memory array; transmitting, by the control circuit, the verification data to the peripheral circuit through the third signal channel or the first signal channel; and transmitting, by the peripheral circuit, seventh synchronization control information to the control circuit through the second signal channel, where the seventh synchronization control information includes an end signal for the write operation.

In some examples, the method further includes: when performing a second read operation, transmitting, by the control circuit, a third command through the first signal channel, where the third command includes a second read command and a second read address; and in response to the third command, transmitting, by the peripheral circuit, second read data stored in the memory array to the control circuit through the first signal channel.

According to an example of the present disclosure, by disposing the memory array, the peripheral circuit coupled to the memory array, and the first bonding contact, the second bonding contact and the third bonding contact respectively coupled to the peripheral circuit in the first semiconductor structure, and by disposing the control circuit, the analog-to-digital conversion circuit and the fourth bonding contact and the fifth bonding contact coupled to the control circuit, and the sixth bonding contact coupled to the analog-to-digital conversion circuit in the second semiconductor structure, after the first semiconductor structure is bonded to the second semiconductor structure, a first signal channel is formed between the first bonding contact and the fourth bonding contact, a second signal channel is formed between the second bonding contact and the fifth bonding contact, a third signal channel is formed between the third bonding contact and the sixth bonding contact, the first signal channel, the second signal channel and the third signal channel are configured to transmit different information, that is, different signal channels are arranged in the semiconductor device to transmit different information, so that the problem of interaction between the first semiconductor structure and the second semiconductor structure can be effectively solved according to different protocol requirements, which in turn making the semiconductor device perform the read, write, and erase operation adapted to the ONFI protocol, and also realize the computing-in-memory function, thereby improving the application range of the semiconductor device.

### BRIEF DESCRIPTION OF THE DRAWINGS

FIG. 1 is a first schematic structural diagram of a semiconductor device according to an example of the present disclosure;

FIG. 2 is a second schematic structural diagram of a semiconductor device according to an example of the present disclosure;

FIG. 3 is a schematic three-dimensional structural diagram of a semiconductor device according to an example of the present disclosure;

FIG. 4 is a schematic distribution diagram of a plurality of memory cells in a memory array according to an example of the present disclosure;

FIG. 5 is a schematic diagram of an example of a first semiconductor structure including a peripheral circuit according to an example of the present disclosure;

FIG. 6 is a schematic cross-sectional view of an example of a memory array including a memory string according to an example of the present disclosure;

FIG. 7 is a schematic diagram of an example of a peripheral circuit according to an example of the present disclosure;

FIG. 8 is a schematic diagram of three signal channels according to an example of the present disclosure;

FIG. 9 is a schematic flowchart of performing a first read operation according to an example of the present disclosure;

FIG. 10 is a schematic diagram of a waveform of a clock signal corresponding to each signal channel during a first read operation according to an example of the present disclosure;

FIG. 11 is a schematic flowchart of performing a first write operation according to an example of the present disclosure;

FIG. 12 is a schematic diagram of a waveform of a clock signal corresponding to each signal channel during a first write operation and a write verification operation according to an example of the present disclosure;

FIG. 13 is a schematic diagram of a semiconductor structure according to an example of the present disclosure;

FIG. 14 is a schematic diagram of a package structure according to an example of the present disclosure;

FIG. 15 is a schematic diagram of an example of a computing-in-memory device having a semiconductor device according to an example of the present disclosure;

FIG. 16 is a schematic diagram of an example of a memory card having a semiconductor device according to an example of the present disclosure; and

FIG. 17 is a schematic diagram of an example of a solid state drive having a semiconductor device according to an example of the present disclosure.

### DETAILED DESCRIPTION

The technical solutions in some examples of the present disclosure will be clearly and completely described below with reference to the examples of the present disclosure and the accompanying drawings, it is obvious that the described examples are only a part of the examples of the present disclosure, and not all examples. All other examples obtained by those of ordinary skill in the art based on the examples of the present disclosure without creative efforts shall fall within the scope of the present disclosure.

In the following description, numerous details are present in order to provide a more thorough understanding of the present disclosure. However, it will be apparent to one skilled in the art that the present disclosure may be practiced without one or more of these details. In other examples, in order to avoid confusion with the present disclosure, some technical features known in the art are not described; that is, not all features of the actual examples are described here, and well-known functions and structures are not described in detail.

In the drawings, the sizes of layers, regions, elements, and their relative sizes may be exaggerated for clarity. Like reference numbers refer to like elements throughout.

It should be appreciated that when an element or layer is referred to as being “on,” “adjacent to,” “connected to,” or “coupled to” another element or layer, it may be directly on, adjacent to, connected to, or coupled to the other element or layer, or there may be intervening element or layer. Conversely, when an element is referred to as being “directly on,” “directly adjacent,” “directly connected to,” or “directly coupled to” another element or layer, there is no intervening element or layer. It should be appreciated that although the terms first, second, third, etc. may be used to describe various elements, components, regions, layers, and/or portions, these elements, components, regions, layers, and/or portions should not be limited by these terms. These terms are used merely to distinguish one element, component, region, layer, or portion from another element, component, region, layer, or portion. Thus, the first element, component, region, layer, or portion discussed below may be represented as a second element, component, region, layer, or portion without departing from the teachings of the present disclosure. When the second element, component, region, layer, or portion is discussed, it is not intended that the present disclosure necessarily includes a first element, component, region, layer, or portion.

For ease of description, spatial relation terms such as “beneath,” “below,” “lower,” “under,” “above,” “upper,” etc., may be employed herein to describe the relationship between one element or feature and other elements or features shown in the figures. It should be appreciated that, in addition to the orientations shown in the figures, the spatial-relation terms intent to further include different orientations of the devices in use and operation. For example, if the devices in the figures are flipped, then elements or features described as “below” or “under” or “beneath” other elements or features will be oriented “on” the other elements or features. Thus, the example terms “below” and “beneath” may include both upper and lower orientations. The devices may be additionally oriented (rotated 90 degrees or other orientations) and the spatial description terminology used herein is interpreted accordingly.

A term used herein is for the purpose of describing a particular example only and is not to be considered as limitation of the present disclosure. As used herein, “a,” “an” and “said/the” in the singular form are intended to include the plural forms as well, unless the context indicated clearly otherwise. It should also be understood that the terms at least one of “consists of” or “comprising,” when used in this description, identify the presence of at least one of stated features, integers, steps, operations, elements or components, but do not exclude the presence and addition of at least one of one or more other features, integers, steps, operations, elements, components or groups. As used herein, the term “at least one of” includes any and all combinations of the related listed items.

For a thorough understanding of the present disclosure, detailed steps and detailed structures will be presented in the following description in order to explain the technical solutions of the present disclosure. Preferred examples of the present disclosure are described in detail below, however, other examples may be provided in addition to these detailed descriptions.

In the classical Von Neumann's computing architecture, the memory and processor are separated, and data is transmitted therebetween through a data bus. When executing commands, the processor first reads data from the memory, processes it, and then writes the updated data back to the memory. Frequent data migration is associated with an undesirable power consumption and latency; in addition, due to the limited bandwidth of the memory, the processing speed of the processor is limited by the access speed of the memory, which greatly affects the computing performance. With the rise of applications such as big data and artificial intelligence, the processing of massive amounts of data has made the bottleneck of Von Neumann's computing architecture increasingly prominent. In order to solve the bottleneck of the classical von Neumann computing architecture, the computing-in-memory chip architecture emerges, and the basic idea is to embed a computation function in the memory device and directly use the memory device to perform logic computation, thereby reducing the amount of data transmission and the transmission distance between the memory and the processor, reducing the power consumption while improving the computation performance, so that a computing system with high computing power, high bandwidth and high energy efficiency is expected to be constructed.

The computing-in-memory chip relies on its own physical properties to have both memory and computing capabilities. The memory capability refers to the ability of different memories to store numerical values by changing their conductivity values according to their physical characteristics, and the computing capability refers to the ability to complete the computation of a vector-matrix multiplication within a certain time according to Ohm's law and Kirchhoff's law by constructing an array composed of memory devices. The computing-in-memory chip includes, but is not limited to, a static random access memory (SRAM), a NAND flash memory, and a dynamic random access memory (DRAM). NAND flash memory is a non-volatile memory and has a large capacity, thus becoming a widely studied object in the computing-in-memory chip.

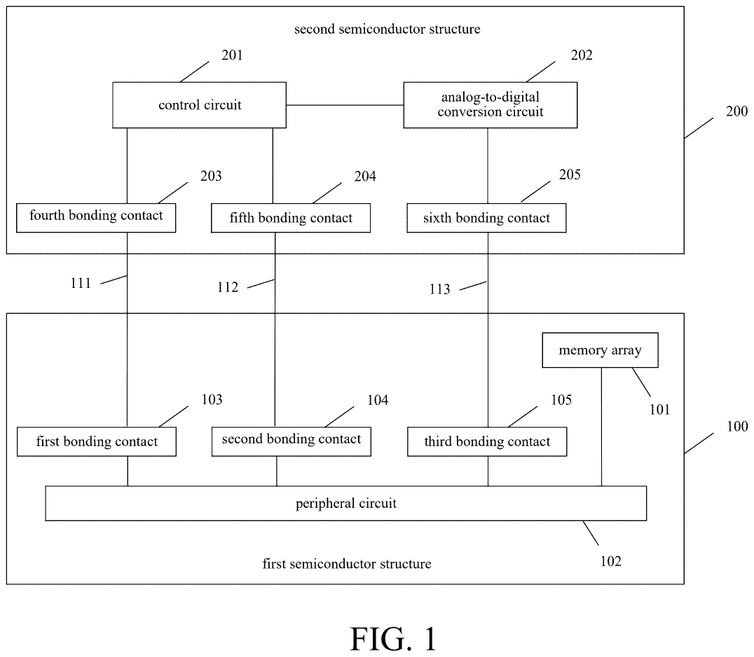

Computing-in-memory chip architecture of a NAND flash memory according to an example of the present disclosure will be described in detail below with reference to the accompanying drawings. Before introducing the semiconductor device shown in FIG. 1, various directions that may be used in the following description are first defined. A stacking direction of the first semiconductor structure and the second semiconductor structure in the semiconductor device is defined as a first direction (e.g., a Z-axis direction). A second direction (e.g., the X-axis direction) and a third direction (e.g., the Y-axis direction) that intersect with each other are defined in a plane perpendicular to the Z-axis direction. In some examples, the X-axis direction, the Y-axis direction, and the Z-axis direction may be perpendicular to each other.

FIG. 1 is a schematic structural diagram of a semiconductor device according to an example of the present disclosure. The semiconductor device includes a first semiconductor structure 100 and a second semiconductor structure 200; the first semiconductor structure 100 includes a memory array 101, a peripheral circuit 102 coupled to the memory array 101, and a first bonding contact 103, a second bonding contact 104, and a third bonding contact 105 respectively coupled to the peripheral circuit 102. The second semiconductor structure 200 includes a control circuit 201, an analog-to-digital conversion circuit (ADC) 202 coupled to the control circuit 201, a fourth bonding contact 203 and a fifth bonding contact 204 respectively coupled to the control circuit 201, and a sixth bonding contact 205 coupled to the analog-to-digital conversion circuit 202. Herein, respective structures may be coupled to each other in any suitable manner.

A first signal channel 111 is formed between the first bonding contact 103 and the fourth bonding contact 203, a second signal channel 112 is formed between the second bonding contact 104 and the fifth bonding contact 204, and a third signal channel 113 is formed between the third bonding contact 105 and the sixth bonding contact 205. The first signal channel 111, the second signal channel 112 and the third signal channel 113 are configured to transmit different information. In this way, the interaction problem between the first semiconductor structure 100 and the second semiconductor structure 200 can be effectively solved according to different protocol requirements, so that the semiconductor device can not only perform operations such as read, write, and erase adapted to the ONFI protocol, but also enable computing-in-memory functions, improving the application range of the semiconductor device.

It should be noted that the drawings corresponding to some examples of the present disclosure are merely example of diagrams, and do not limit specific positions and direct connection relationships of corresponding circuits and memory arrays in the diagrams. For example, an interconnection layer may further be included between the bonding contact and the corresponding circuit and the memory array, the interconnection layer includes a metal layer of multilayer wiring, and a connection between the bonding contact and the corresponding circuit is achieved through the metal layer of the multilayer wiring.

In some examples, the first semiconductor structure 100 and the second semiconductor structure 200 are stacked on each other along the Z-axis direction, moreover, the memory array 101 and the peripheral circuit 102 in the first semiconductor structure 100 may also be stacked on each other along the Z-axis direction, so that the overall size of the semiconductor device may be reduced.

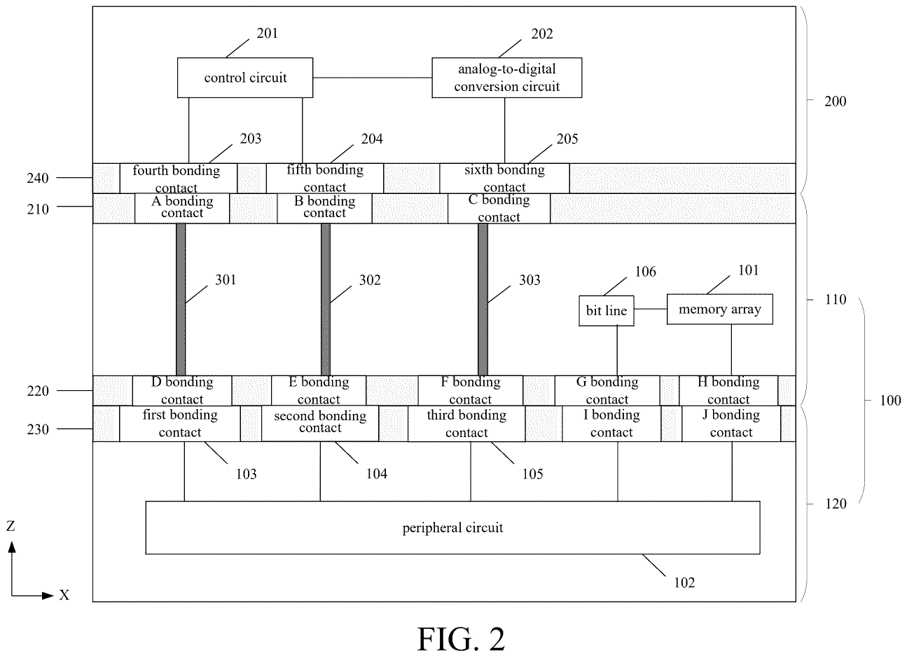

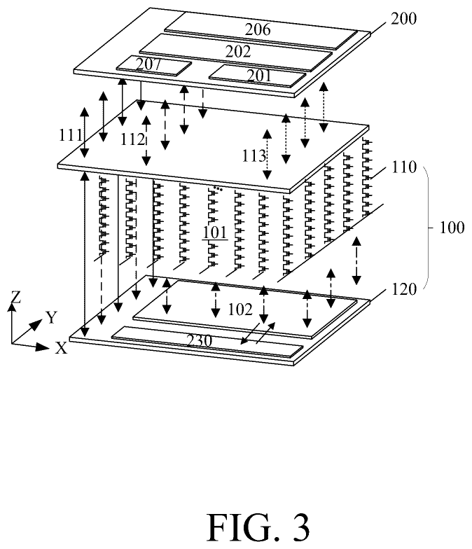

FIG. 2 exemplarily shows a cross-sectional structural schematic diagram of another semiconductor device; and FIG. 3 exemplarily shows a schematic three-dimensional structural diagram of the semiconductor device corresponding to FIG. 2. As shown, the first semiconductor structure 100 includes a first sub-semiconductor structure 110 formed with a memory array 101, and a second sub-semiconductor structure 120 formed with a peripheral circuit 102, a first bonding contact 103, a second bonding contact 104 and a third bonding contact 105, and the first sub-semiconductor structure 110 and the second sub-semiconductor structure 120 are stacked on each other along the Z-axis direction.

In some examples, the first sub-semiconductor structure 110, the second sub-semiconductor structure 120, and the second semiconductor structure 200 may be formed on different substrates in parallel. For example, the first sub-semiconductor structure 110 is formed on the first substrate, the second sub-semiconductor structure 120 is formed on the second substrate, and the second semiconductor structure 200 is formed on the third substrate. Various suitable bonding techniques, such as hybrid bonding, transfer bonding, and the like, are then used to stack the first sub-semiconductor structure 110, the second sub-semiconductor structure 120, and the second semiconductor structure 200. Herein, the second semiconductor structure 200 and the first sub-semiconductor structure 110, and the first sub-semiconductor structure 110 and the second sub-semiconductor structure 120, may be bonded by using, for example, hybrid bonding (also referred to as “metal/dielectric hybrid bonding connection”), transfer bonding, anodic bonding, fusion bonding, adhesive bonding, and eutectic bonding, and the like.

In some examples, as shown in FIG. 2, the first sub-semiconductor structure 110 is located between the second sub-semiconductor structure 120 and the second semiconductor structure 200. In other words, the second semiconductor structure 200 is coupled to the first sub-semiconductor structure 110, and one side of two opposite sides of the first sub-semiconductor structure 110 along the Z-axis direction away from the second semiconductor structure 200 is coupled to the second sub-semiconductor structure 120. The second semiconductor structure 200 may be coupled to an external device, such as a host. In some examples of the present disclosure, by vertically integrating the first sub-semiconductor structure 110, the second sub-semiconductor structure 120, and the second semiconductor structure 200, the chip size may be reduced, and the memory density may be increased. In addition, integrating the control circuit 201 in the second semiconductor structure 200 may shorten a distance between the control circuit 201 and the peripheral circuit 102, thereby reducing signal delay.

In some examples, referring to FIG. 2, the first sub-semiconductor structure 110 includes a first bonding layer 210 and a second bonding layer 220. The first bonding layer 210 and the second bonding layer 220 are respectively located on two opposite sides of the memory array 101 along the Z-axis direction, and the second sub-semiconductor structure 120 includes a third bonding layer 230 formed with the first bonding contact 103, the second bonding contact 104, and the third bonding contact 105. The second semiconductor structure 200 includes a fourth bonding layer 240 formed with a fourth bonding contact 203, a fifth bonding contact 204, and a sixth bonding contact 205, where the first bonding layer 210 and the fourth bonding layer 240 are bonded, the second bonding layer 220 and the third bonding layer 230 are bonded, so that the first bonding contact 103 and the fourth bonding contact 203 are coupled to form the first signal channel 111, the second bonding contact 104 and the fifth bonding contact 204 are coupled to form the second signal channel 112, and the third bonding contact 105 and the sixth bonding contact 205 are coupled to form the third signal channel 113.

In some examples, the bonding contacts may include conductive materials including, but not limited to, tungsten (W), cobalt (Co), copper (Cu), aluminum (Al), silicide, or any combination thereof. In an example, the bonding contact of the bonding layer includes Cu. The remaining regions of the bonding layer may be formed of a dielectric including, but not limited to, silicon oxide, silicon nitride, silicon oxynitride, a low-k dielectric, or any combination thereof. The bonding contacts and the surrounding dielectric in the bonding layer may be used for hybrid bonding, and metal-to-metal bonding and dielectric-to-dielectric bonding may be obtained simultaneously.

Referring to FIG. 2, the semiconductor device further includes: a first connection structure 301 through the memory array 101 and connected to the first bonding contact 103 and the fourth bonding contact 203 respectively; therefore, the control circuit 201 in the first semiconductor structure may be connected to the peripheral circuit 102 through the fourth bonding contact 203, the first connection structure 301, and the first bonding contact 103, thereby forming the first signal channel 111.

Referring to FIG. 2, the semiconductor device further includes a second connection structure 302 through the memory array 101 and connected to the second bonding contact 104 and the fifth bonding contact 204 respectively. Therefore, the control circuit 201 in the first semiconductor structure may be connected to the peripheral circuit 102 through the fifth bonding contact 204, the second connection structure 302, and the second bonding contact 104, thereby forming the second signal channel 112.

Referring to FIG. 2, the semiconductor device further includes a third connection structure 303 through the memory array 101 and connected to the third bonding contact 105 and the sixth bonding contact 205, respectively. Therefore, the analog-to-digital conversion circuit 202 in the first semiconductor structure may be connected to the peripheral circuit 102 through the sixth bonding contact 205, the third connection structure 303, and the third bonding contact 105, thereby forming the third signal channel 113. In actual operation, the first connection structure 301, the second connection structure 302 and the third connection structure 303 may be through array contacts (TAC).

It should be noted that a bonding contact connected to each circuit or the memory array is disposed in each bonding layer, and each bonding contact is disposed in the same way. In the above examples of the present disclosure, only some of the bonding contacts are described, and in some other examples, referring to FIG. 2, the first bonding layer 210 may further include an A bonding contact, a B bonding contact, and a C bonding contact, the second bonding layer 220 may further include a D bonding contact, an E bonding contact, an F bonding contact, a G bonding contact, and an H bonding contact, and the third bonding layer 230 may further include an I bonding contact and a J bonding contact.

For example, the fourth bonding contact 203 is bonded to the A bonding contact, the fifth bonding contact 204 is bonded to the B bonding contact, the sixth bonding contact 205 is bonded to the C bonding contact, the first bonding contact 103 is bonded to the D bonding contact, the second bonding contact 104 is bonded to the E bonding contact, the third bonding contact 105 is bonded to the F bonding contact, the G bonding contact is bonded to the I bonding contact, and the H bonding contact is bonded to the J bonding contact.

In some examples, referring to FIG. 2, the first semiconductor structure 100 further includes a bit line (BL) 106 located between the memory array 101 and the peripheral circuit 102, and coupled to the memory array 101 and the peripheral circuit 102, respectively. In actual operation, the first semiconductor structure 100 may include a plurality of bit lines 106. Each bit line 106 may be coupled to a plurality of memory cells in the memory array 101. In some examples of the present disclosure, the memory array 101 may be coupled to the peripheral circuit 102 through the bit line 106, the G bonding contact and the I bonding contact, or may be coupled to the peripheral circuit 102 through the H bonding contact and the J bonding contact. In actual operation, different transmission paths between the memory array 101 and the peripheral circuit 102 may be selected according to different protocol requirements. The following describes a detailed description of the transmission path, and details are not described here again.

In some examples, the first semiconductor structure includes a three-dimensional NAND type memory, that is, the memory array is a NAND type memory array, that is, the memory cell is a NAND memory cell.

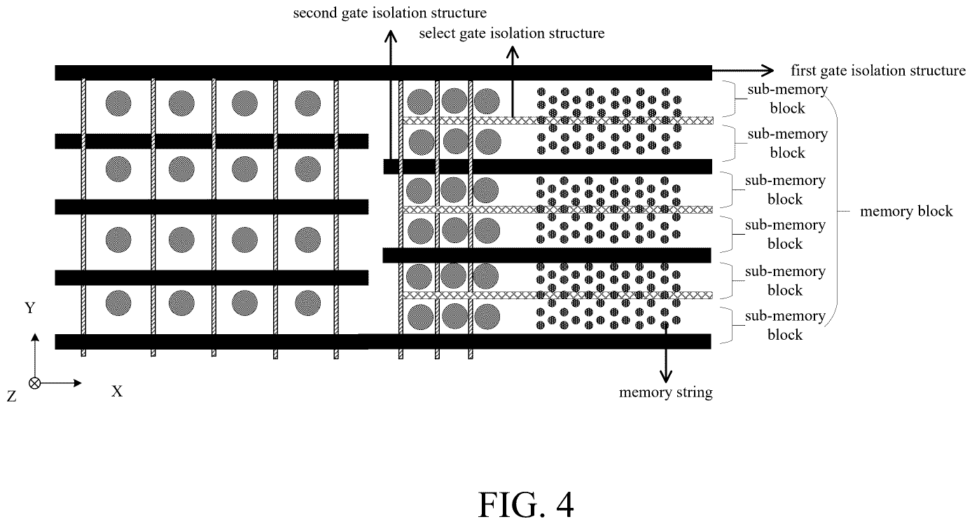

In some examples, the memory array 101 may include a plurality of memory planes, each memory plane may include a plurality of memory banks, each memory bank may include a plurality of memory blocks, each memory block may include a plurality of sub-memory blocks, each sub-memory block may include a plurality of memory strings, and each memory string may include a plurality of memory cells connected in series. For example, FIG. 4 exemplarily shows a schematic distribution diagram of a plurality of memory cells in a memory array 101. As shown in FIG. 4, the memory array includes rows of memory cell rows parallel to the gate isolation structure GLS that are staggered in parallel; each two rows of memory cell rows are separated by a gate isolation structure and a select gate isolation structure, each memory cell row includes a plurality of memory strings arranged along the X direction; one memory cell in each memory string is shown in FIG. 4, and the remaining memory cells and the memory cell are stacked along the Z direction. Here, the select gate isolation structure may be a top select gate isolation structure TSG CUT, which divides the top select gate TSG into a plurality of top select lines. The select gate isolation structure may also be a bottom select gate isolation structure BSG CUT, which divides the bottom select gate BSG into a plurality of bottom select lines. The gate isolation structure may include a first gate isolation structure and a second gate isolation structure, the first gate isolation structure divides the memory array into a plurality of memory blocks, and the plurality of second gate isolation structures may divide the memory block into a plurality of sub-memory blocks. FIG. 4 exemplarily shows only one memory block of the memory, but the memory may include a plurality of memory blocks as shown in FIG. 4, adjacent memory blocks are separated by the first gate isolation structure, and the plurality of memory blocks may be arranged along the Y direction.

It should be noted that the number of rows of memory cell rows between the gate isolation structure and the select gate isolation structure shown in FIG. 4 is merely an example, and is not intended to limit the number of memory cell rows included in one sub-memory block of the 3D NAND type memory in the present disclosure. In practical applications, the number of memory cell rows included in one sub-memory block may be adjusted according to actual conditions, such as 2, 4, 8, 16, etc.

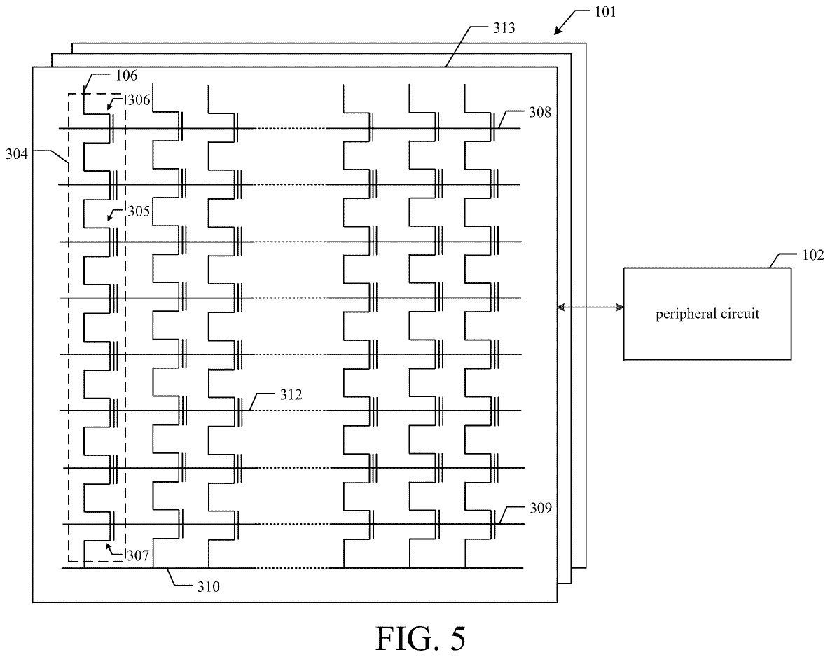

FIG. 5 is a schematic diagram of an example of second semiconductor structure including a peripheral circuit according to an example of the present disclosure. The second semiconductor structure may include a memory array 101 and a peripheral circuit 102 coupled to the memory array 101. Taking an example in which the memory array 101 is a 3D NAND type memory array for description, where the memory cell 305 is a NAND memory cell, the memory cell 305 is provided in the form of an array of memory strings 304, and each memory string 304 extends vertically. In some examples, each memory string 304 includes a plurality of memory cells 305 coupled in series and stacked vertically. Each memory cell 305 may maintain a continuous analog value, e.g., voltage or charge, depending on the number of electrons captured within the area of the memory cell 305. Each memory cell 305 may be a floating gate type memory cell including a floating gate transistor, or a charge trapping type memory cell including a charge trapping transistor.

In some examples, each memory cell 305 is a single level cell (SLC) having two possible memory states and thus may store one bit of data. For example, the first memory state “0” may correspond to a first voltage range and the second memory state “1” may correspond to a second voltage range. In some examples, each memory cell 305 is a multi-level cell capable of storing more than a single bit of data in four or more memory states, e.g., a multi-level cell (MLC) storing two bits per cell, a triple level cell (TLC) storing three bits per cell, or a quad-level cell (QLC) storing four bits per cell.

As shown in FIG. 5, each memory string 304 may include a bottom select gate (BSG) 307 at its source terminal and a top select gate (TSG) 306 at its drain terminal. The bottom select gate 307 and the top select gate 306 may be configured to activate the selected memory string 304 during read and program operations. In some examples, the source terminals of the memory strings 304 in the same memory block 313 may be coupled through a common source line (CSL) 310. In other words, all the memory strings 304 in the same memory block 313 have an array common source (ACS). According to some examples, the top select gate 306 of each memory string 304 is coupled to a respective bit line 106 from which data may be read or written via an output bus (not shown). In some examples, each memory string 304 is configured to be selected or deselected by applying a select voltage (e.g., a voltage higher than a threshold voltage of the top select gate 306) or a deselect voltage (e.g., 0V) to the respective top select gate 306 through one or more top select lines (TSL) 308 and/or by applying a select voltage (e.g., a voltage above a threshold voltage of the bottom select gate 307) or a deselect voltage (e.g., 0V) to the respective bottom select gate 307 through one or more bottom select lines (BSL) 309.

As shown in FIG. 5, the memory string 304 may be organized into a plurality of memory blocks 313, each of which may have a common source line 310. In some examples, each memory block 313 is a basic data unit for an erase operation, e.g., all memory cells 305 on the same memory block 313 are erased simultaneously. To erase the memory cells 305 in the selected memory block, a common source line 310 coupled to the selected memory block and unselected memory blocks in the same plane as the selected memory block may be biased with an erase voltage. It should be understood that in some examples, the erase operation may be performed on a half-memory block level, a quarter-memory block level, or a level having any suitable number of memory blocks or any suitable fractions of a memory block. Memory cells 305 in adjacent memory strings 304 may be coupled by word lines 312 that select which row of memory cells 305 is affected by read or program operations.

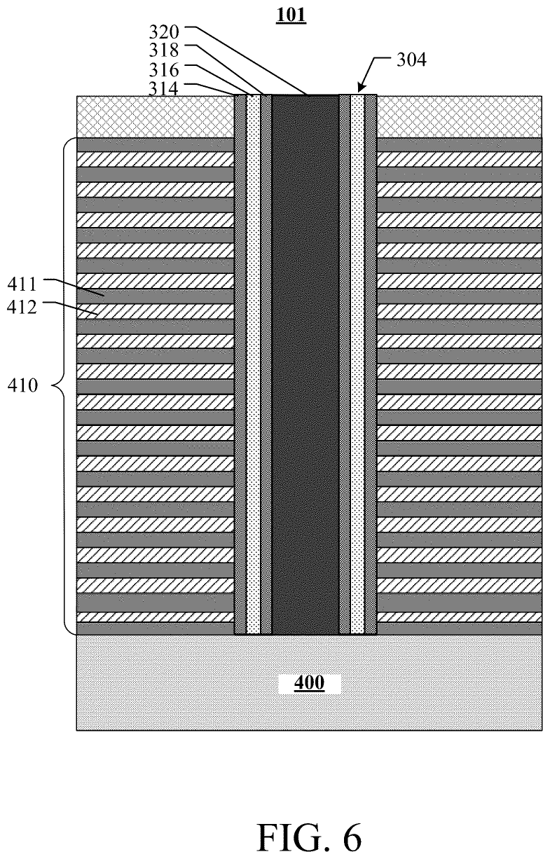

FIG. 6 is a schematic cross-sectional view of an example of memory array including a memory string according to an example of the present disclosure. As shown in FIG. 6, the memory array 101 may include a stack structure 410, the stack structure 410 includes a plurality of gate layers 411 and a plurality of insulating layers 412 alternately stacked in sequence, and a channel structure vertically through the gate layer 411 and the insulating layer 412, the channel structure and each of the gate layers 411 are coupled to form a memory cell, and the channel structure is coupled to the plurality of gate layers in the stack structure 410 to form a memory string 304. The gate layer 411 and the insulating layer 412 may be alternately stacked, and two adjacent gate layers 411 are separated by one insulating layer 412.

The composition material of the gate layer 411 may include a conductive material. The conductive material includes, but is not limited to, tungsten (W), cobalt (Co), copper (Cu), aluminum (Al), polysilicon, doped silicon, silicide, or any combination thereof. In some examples, each gate layer 411 includes a metal layer, such as a tungsten layer. In some examples, each gate layer 411 includes a doped polysilicon layer. Each gate layer 411 may include a control gate surrounding the memory cell. The gate layer 411 at the top of the stack structure 410 may extend laterally as a top select gate line, the gate layer 411 at the bottom of the stack structure 410 may extend laterally as a bottom select gate line, and the gate layer 411 extending laterally between the top select gate line and the bottom select gate line may act as a word line layer. The top select gate line is used to form the top select gate 306, and the bottom select gate line is used to form the bottom select gate 307.

In some examples, the stack structure 410 may be disposed on the substrate 400. The substrate 400 may include silicon (e.g., monocrystalline silicon), silicon germanium (SiGe), gallium arsenide (GaAs), germanium (Ge), silicon-on-insulator (SOI), germanium-on-insulator (GOI), or any other suitable material. In other examples, the semiconductor device may also not include a substrate.

In some examples, the memory string 304 includes a channel structure that extends vertically through the stack structure 410. In some examples, the channel structure includes a channel hole filled with a semiconductor material(s) (e.g., as a semiconductor channel) and a dielectric material(s) (e.g., as a memory film). In some examples, the semiconductor channel includes silicon, e.g., polysilicon. In some examples, the memory film is a composite dielectric layer including a tunneling layer, a memory layer (also referred to as a “charge trapping/storage layer”), and a blocking layer. The channel structure may have a cylindrical shape (e.g., a pillar shape). According to some examples, the semiconductor channel, the tunneling layer, the storage layer, and the blocking layer are arranged radially from the center of the pillar toward the outer surface of the pillar in this order. The tunneling layer may include silicon oxide, silicon oxynitride, or any combination thereof. The storage layer may include silicon nitride, silicon oxynitride, or any combination thereof. The blocking layer may include silicon oxide, silicon oxynitride, a high dielectric constant (high-k) dielectric, or any combination thereof. In one example, the memory film may include a composite layer of silicon oxide/silicon oxynitride/silicon oxide (ONO).

In some examples, referring back to FIG. 5, the peripheral circuit 102 may include any suitable analog, digital, and mixed-signal circuit for enabling operation of the memory array 101 by applying voltage signals and/or current signals to and sensing voltage signals and/or current signals from each target memory cell through the bit line 106, the word line 312, the common source line 310, the bottom select line 309, and the top select line 308. Peripheral circuit 102 may include various types of peripheral circuit formed using metal-oxide-semiconductor technology.

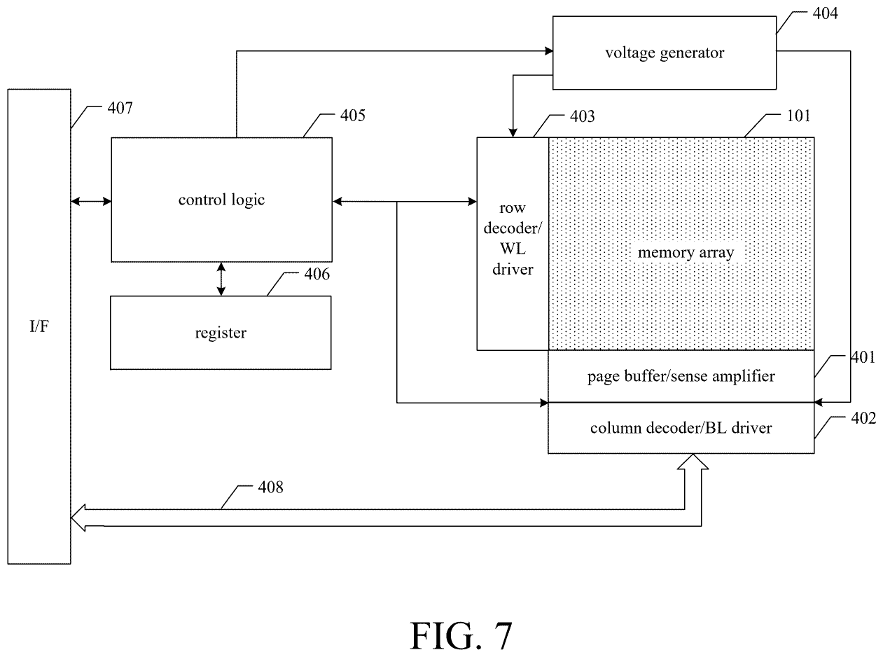

FIG. 7 illustrates some example of peripheral circuits including a page buffer/sense amplifier 401, a column decoder/bit line driver 402, a row decoder/word line driver 403, a voltage generator 404, a control logic 405, a register 406, a flash interface I/F 407, and a data bus 408. It should be understood that in some examples, the peripheral circuit may also include an additional peripheral circuit not shown in FIG. 7.

The page buffer/sense amplifier 401 may be configured to read data from and program (write) data to the memory array 101 according to control signals from the control logic 405. In one example, the page buffer/sense amplifier 401 may store a page of program data (write data) to be programmed to the memory array 101. In another example, the page buffer/sense amplifier 401 may perform a program verification operation to ensure that data has been properly programmed into memory cells coupled to the selected word line. In yet another example, the page buffer/sense amplifier 401 may also sense a low power signal from the bit line representing a data bit stored in the memory cell, and amplify the small voltage swing to an identifiable logic level in a read operation. Column decoder/bit line driver 402 may be configured to be controlled by the control logic 405 and select one or more memory cell strings by applying a bit line voltage generated from the voltage generator 404.

The row decoder/word line driver 403 may be configured to be controlled by the control logic 405 and select/deselect a memory block of the memory array 101 and select/deselect a word line of the memory block. The row decoder/word line driver 403 may also be configured to drive a word line using the word line voltage generated from the voltage generator 404. In some examples, the row decoder/word line driver 403 may also select/deselect and drive the bottom select line and the top select line. As described in detail below, the row decoder/word line driver 403 is configured to perform a program operation on memory cells coupled to the selected word line(s). The voltage generator 404 may be configured to be controlled by the control logic 405 and generate word line voltages (e.g., read voltages, program voltages, pass voltages, local voltages, verify voltages, etc.), bit line voltages, and source line voltages to be supplied to the memory array 101.

Control logic 405 may be coupled to each peripheral circuit described above and configured to control operation of each peripheral circuit. Register 406 may be coupled to control logic 405 and include status registers, command registers, and address registers for storing status information, command operation code (OP code), and command address for controlling operation of each peripheral circuit. Flash interface 407 may be coupled to control logic 405 and act as a control buffer to buffer control commands received from a host-side device (not shown) and relay them to the control logic 405 and buffer status information received from the control logic 405 and relay it to a memory controller. Flash interface 407 may also be coupled to a column decoder/bit line driver 402 via data bus 408 and act as a data I/O interface and a data buffer to buffer data and relay it to the memory array 101, or relay or buffer data from the memory array 101.

In some examples, referring back to FIG. 3, the second semiconductor structure 200 may further include a digital processing circuit 206 and an interface circuit 207 coupled to the control circuit 201. The digital processing circuit 206 may include a special-purpose processor including, but not limited to, a CPU, a GPU, a digital signal processor (DSP), a tensor processing unit (TPU), a visual processing unit (VPU), a neural processing unit (NPU), a synergistic processing unit (SPU), a physics processing unit (PPU), and an image signal processor (ISP). In an example, the NPU may perform operations such as arithmetic/logical operations, rotation and shift operations, compensation operations, activation operations, and pooling operations, and the like. The interface circuit 207 may be used to receive and transmit data between a semiconductor device and other external devices. In some examples the interface circuit 207 is configured to output the operation result after the operation performed by the digital processing circuit 206 to the external device.

Herein, the control circuit 201 may be configured to control the operation of the first semiconductor structure 100 and the second semiconductor structure 200. That is, the control circuit 201 may act as a memory controller that manages data storage and transmission in the second semiconductor structure 200 and an operation controller that manages data operations and transmissions in the first semiconductor structure 100. In some examples, the control circuit 201 is further configured to control data transmission between the first semiconductor structure 100 and the second semiconductor structure 200. In some examples, the control circuit 201 is further configured to receive the input data sent by the external device, and send the input data to the first semiconductor structure 100.

Herein, the analog-to-digital conversion circuit 202 may convert the current signal/voltage signal output by the memory array 101 into a digital signal. The control circuit 201 and the digital processing circuit 206 may perform various operations on the digital signal. Then, the operation results after the control circuit 201 and the digital processing circuit 206 have performed operations are output to the external device through the interface circuit 207.

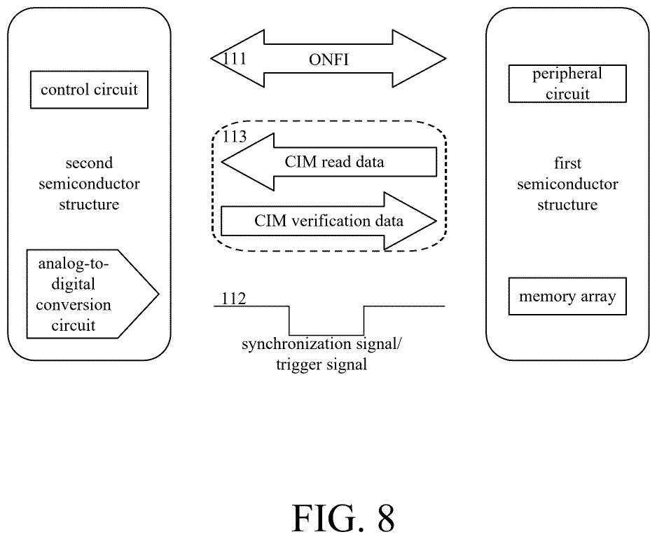

As previously described, different transmission paths between circuits and memory arrays may be selected according to different protocol requirements. In some examples of the present disclosure, the first signal channel 111, the second signal channel 112 and the third signal channel 113 may transmit different information in combination with different protocol requirements and different needs of the control circuits. For example, referring to FIG. 8, the first signal channel 111 is configured to transmit system information adapted to the ONFI protocol and system information between the control circuit and the peripheral circuit in performing a computing-in-memory (CIM) process. The second signal channel 112 is configured to transmit synchronization control information between the peripheral circuit and the control circuit in performing the computing-in-memory CIM process. The third signal channel 113 is configured to transmit system information between the memory array and the analog-to-digital conversion circuit in performing the computing-in-memory CIM process.

In some examples, the first signal channel 111 is mainly used to transmit command information, address information, data information (write data or read data), status/feature information (Status/Feature), and the like in the process of performing a read/write operation adapted to the ONFI protocol, and transmit a part of interaction information, such as command information, data information (weight matrix, input vector data), and the like, between the control circuit and the peripheral circuit in performing the computing-in-memory CIM process. The second signal channel 112 is mainly used to transmit synchronization control information, such as a synchronization signal and a trigger signal, exchanged between the peripheral circuit and the control circuit in performing the computing-in-memory CIM process. For example, the synchronization signal may be used to coordinate the timing of the entire system, and the trigger signal may be used to trigger a specific event or operation. The third signal channel 113 is mainly used to transmit data information, such as CIM read data and CIM verification data, in performing the computing-in-memory CIM process.

It should be noted that in the process of performing the computing-in-memory CIM writing operation of the CIM, the memory array 101 may be configured to store a weight matrix. In some examples, the plurality of weights in the weight matrix may be written into the memory array 101 according to a certain mapping rule.

In the process of performing the computing-in-memory CIM reading operation of the CIM, the semiconductor device needs to implement an operation of the input vector data and the weight matrix, the input vector data may be an input vector including a plurality of elements, and the weight matrix includes a plurality of weights. A multiply-accumulate operation needs to performed on each element in the input vector data and a plurality of weights in the weight matrix to obtain a corresponding element in the output data. In the operation phase, the first semiconductor structure may receive the input vector data from an external device, and each element in the input vector data may be converted into an input voltage by a digital-to-analog conversion circuit (DAC) to be input into the memory array by a bit line or a word line. After the multiply-accumulate operation of the input vector data and the weight matrix, the computing-in-memory current signal corresponding to the operation result is output through the bit line, the computing-in-memory current signal enters the analog-to-digital conversion circuit (ADC) through the peripheral circuit, and analog-to-digital conversion is performed in the analog-to-digital conversion circuit, and then, the analog-to-digital conversion circuit transmits the conversion result to the control circuit to output the final read data.

The transmission of the three signal channels in the read/write operation of the computing-in-memory CIM is described below with reference to the accompanying drawings.

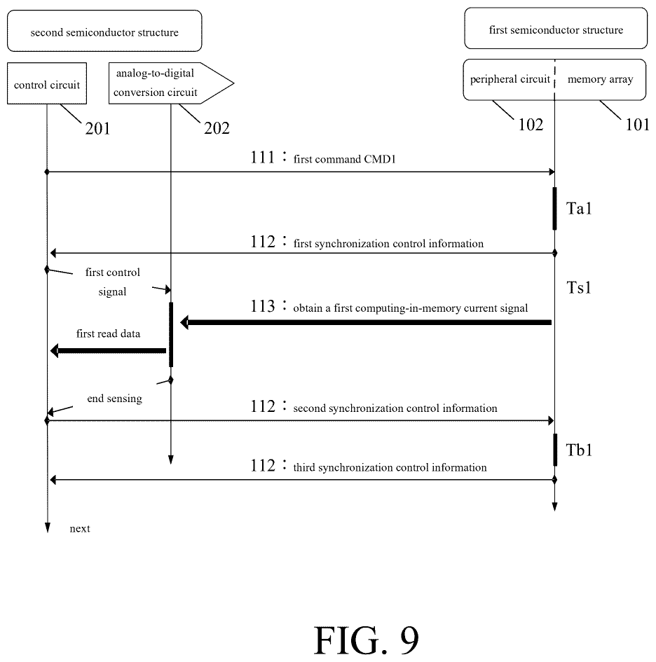

In some examples, with reference to FIG. 2 and FIG. 9, when performing the first read operation, e.g., the CIM read operation, the control circuit 201 is configured to: send a first command CMD1 through the first signal channel 111, where the first command CMD1 is configured to indicate to perform the CIM read operation; that is, perform vector multiply-accumulate operation on the input vector data and the weight array, and read out the operation result. In this case, the first command CMD1 includes a first read command (CIM Read CMD), a first read address (CIM Read Add), and input vector data (CIM Read Input data).

The peripheral circuit 102 is configured to: receive and in response to the first command CMD1, transmit first synchronization control information through the second signal channel 112, where the first synchronization control information includes a trigger signal for the first read operation to start sensing. It should be noted that, before sending the first synchronization control information, the peripheral circuit 102 is further configured to: obtain state information of the memory array 101, where the state information is configured to represent whether the memory array 101 currently can perform a computing-in-memory read operation (CIM Read). In this process, the running (Array setting) duration of the memory array 101 is, for example, Ta1.

The control circuit 201 is configured to: receive the first synchronization control information, and send a first control signal to the analog-to-digital conversion circuit 202, where the first control signal is configured to indicate to obtain a first computing-in-memory current signal output by the memory array 101. Here, the first computing-in-memory current signal output by the memory array 101 is transmitted to the peripheral circuit 102 through the bit line 106, and then transmitted to the analog-to-digital conversion circuit 202 from the peripheral circuit 102 through the third signal channel 113.

The analog-to-digital conversion circuit 202 is configured to: in response to the first control signal, obtain the first computing-in-memory current signal through the third signal channel 113, and convert the first computing-in-memory current signal into first read data. In this process, the duration in which the analog-to-digital conversion circuit 202 senses and obtains the first computing-in-memory current signal is, for example, Ts1; that is, the sampling time of the analog-to-digital conversion circuit 202 is Ts1.

The control circuit 201 is configured to: obtain the first read data and a trigger signal for the analog-to-digital conversion circuit 202 to end sensing, and send second synchronization control information to the peripheral circuit 102 through the second signal channel 112, where the second synchronization control information includes a trigger signal for sensing completion of the first read operation.

The peripheral circuit 102 is configured to: receive the second synchronization control information, and send third synchronization control information to the control circuit 201 through the second signal channel 112. The third synchronization control information includes an end signal for the first read operation. Here, the duration from the completion of sensing of the analog-to-digital conversion circuit 202 to the end of the first read operation is, for example, Tb1. As such, one CIM read operation is completed.

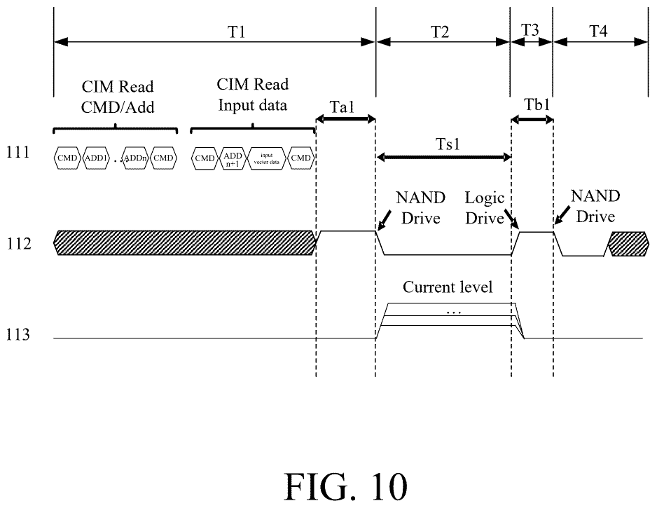

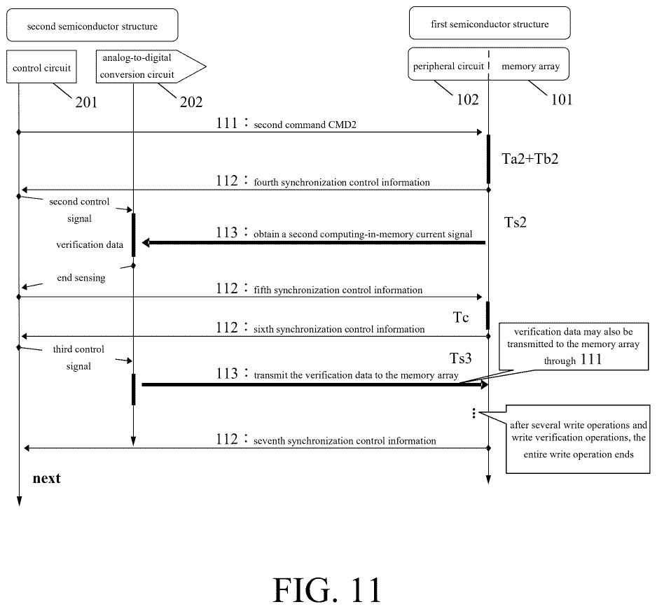

FIG. 10 is a schematic diagram of waveforms of clock signals corresponding to each signal channel during a first read operation according to an example of the present disclosure. With reference to FIG. 9 and FIG. 10, in a first period T1, the first command CMD1 is transmitted through the first signal channel 111, the first command CMD1 includes a first read command (CIM Read CMD), a first read address (CIM Read Add), and input vector data (CIM Read Input data). The first period T1 includes a duration Ta1 in which the memory array 101 runs. In the second period T2, the first semiconductor structure drive (labeled as NAND Drive in FIG. 10) generates a signal (that is, the first synchronization control information) for indicating that the first read operation may start, and transmits the first synchronization control information to the control circuit 201 through the second signal channel 112. The analog-to-digital conversion circuit 202 obtains the first computing-in-memory current signal (labeled as Current level in FIG. 10) through the third signal channel 113. In the third period T3, the sensing of the third signal channel 113 is completed, the second semiconductor structure drive (labeled as Logic Drive in FIG. 11) generates a trigger signal (e.g., the second synchronization control information) for sensing completion of the first read operation, and transmits the second synchronization control information to the peripheral circuit 102 through the second signal channel 112. In the fourth period T4, the peripheral circuit 102 transmits the third synchronization control information through the second signal channel 112. It should be understood that the first period T1 is earlier than the second period T2, the second period T2 is earlier than the third period T3, and the third period T3 is earlier than the fourth period T4.

It should be noted that, after the multiply-accumulate operation is performed on the input vector data and the plurality of weights in the weight matrix in the memory array, a first computing-in-memory current signal is output.

In some examples, with reference to FIG. 2 and FIG. 11, when performing a first write operation, e.g., a write operation of the computing-in-memory (CIM Pgm), the control circuit 201 is configured to: send a second command CMD2 through the first signal channel 111, where the second command CMD2 includes write data, and the second command CMD2 indicates to store the write data in the memory array 101. The write data described herein may be understood as the weight matrix described in the foregoing examples, that is, the CIM write data. In other words, the second command CMD2 includes a first write instruction (CIM Pgm CMD), a first write address (CIM Pgm Add), and a weight matrix (CIM Pgm Input data). The peripheral circuit 102 is configured to: receive and in response to the second command CMD2, store the weight matrix in the memory array 101. Herein, in the process of storing the weight matrix, the plurality of weights in the weight matrix may be stored in the memory array 101 according to a certain mapping rule. As such, one CIM write operation is completed.

It should be noted that one complete write cycle includes one write operation (Pgm) and one write verification operation (Pgm Verify); based on this, a write verification operation is performed on the memory array after the first write operation is performed to determine whether the weight matrix is stored in the memory array, thereby ensuring correctness and reliability of the first write operation. Here, the duration in which the first write operation is performed (Pgm pulse) is, for example, Ta2, and the duration in which the write verification operation is prepared (Verify ready) is, for example, Tb2.

In some examples, with reference to FIG. 2 and FIG. 11, when performing the write verification operation, e.g., a program verification of the computing-in-memory (CIM Pgm Verify), the peripheral circuit 102 is configured to: send fourth synchronization control information through the second signal channel 112, where the fourth synchronization control information includes state information of the memory array 101, and the state information is configured to represent whether the memory array 101 currently can perform a write verification operation (CIM Pgm Verify). The control circuit 201 is configured to: receive the fourth synchronization control information and send a second control signal to the analog-to-digital conversion circuit 202, where the second control signal is configured to indicate to obtain a second computing-in-memory current signal of the memory array. The analog-to-digital conversion circuit 202 is configured to: in response to the second control signal, sense through the third signal channel 113 and obtain the second computing-in-memory current signal output by the memory array 101, and convert the second computing-in-memory current signal into CIM verification data, and the control circuit 201 obtains the CIM verification data and a trigger signal for the analog-to-digital conversion circuit 202 to end sensing. In this process, the duration in which the analog-to-digital conversion circuit 202 senses and obtains the computing-in-memory current signal is, for example, Ts2, that is, the sampling time of the analog-to-digital conversion circuit 202 is Ts2.

The control circuit 201 is configured to: verify with CIM verification data and the CIM write data (here, the weight matrix), e.g., compare the CIM write data with the CIM verification data. After the verification is completed, the fifth synchronization control information is sent through the second signal channel 112, where the fifth synchronization control information includes a completion signal for the verification operation (CIM verify completion). Here, the duration from the completion of the verification operation to the end of the write verification operation is, for example, Tc.

The peripheral circuit 102 is configured to: send sixth synchronization control information through the second signal channel 112, where the sixth synchronization control information includes a signal for storing the verification data to the memory array. The control circuit 201 is configured to: send a third control signal to the analog-to-digital conversion circuit 202, where the third control signal indicates to transmit the CIM verification data to the memory array 101. In some examples, the CIM verification data may be transmitted to the memory array 101 through the third signal channel 113, and in other examples, the CIM verification data may also be transmitted to the memory array 101 through the first signal channel 111, which is not limited in the present disclosure. In this way, one CIM write verification operation is completed. That is, one full write cycle is completed.

Next, it is determined whether a second write cycle is required according to a result of the verification operation, where when the verification result indicates that the write verification operation passes, the write cycle does not need to be performed again, and when the verification result indicates that the write verification operation fails, the write cycle needs to be performed again. As such, after several first write operations and write verification operations, the entire CIM write operation ends. In this case, the peripheral circuit 102 is configured to: send seventh synchronization control information through the second signal channel 112, where the seventh synchronization control information includes an end signal for the CIM write operation (CIM Pgm End).

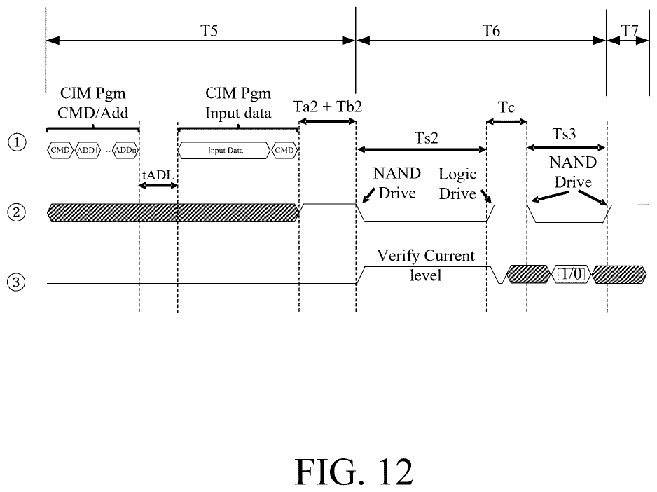

In some examples, FIG. 12 is a schematic diagram of waveforms of clock signals corresponding to each signal channel during a first write operation and a write verification operation according to an example of the present disclosure. With reference to FIG. 11 and FIG. 12, in a fifth period T5, a second command CMD2 is transmitted through the first signal channel 111, and the CIM write data (here the weight matrix) is stored in the memory array 101 according to the instruction of the second command CMD2. The second command CMD2 includes a first write command (CIM Pgm CMD), a first write address (CIM Pgm Add), and a weight matrix (CIM Pgm Input data). The fifth period T5 includes: the duration in which the write operation is performed (Pgm pulse), for example, Ta2, and the duration in which the write verification operation is prepared (Verify ready), for example, Tb2.

In a sixth period T6, the first semiconductor structure drive (labeled as NAND Drive in FIG. 12) generates fourth synchronization control information including state information that the memory array 101 may perform a write verification operation (CIM Pgm Verify), and transmits the fourth synchronization control information through the second signal channel 112. Then, the second computing-in-memory current signal (labeled as Verify Current level in FIG. 12) is transmitted through the third signal channel 113, and the analog-to-digital conversion circuit 202 converts the second computing-in-memory current signal into the verification data. Here, the duration in which the analog-to-digital conversion circuit 202 senses and obtains the second computing-in-memory current is Ts2. After the control circuit 201 verifies the CIM write data and the CIM verification data, the control circuit 201 transmits fifth synchronization control information through the second signal channel 112. The fifth synchronization control information includes a completion signal for the verification operation (CIM verify completion). Here, the duration from the completion of the verification operation to the end of the write verification operation is, for example, Tc. Next, the peripheral circuit 102 transmits sixth synchronization control information through the second signal channel, and transmits the verification data through the third signal channel or the first signal channel. In this process, the duration in which the verification data is transferred is Ts3.

In a seventh period T7, the peripheral circuit 102 transmits seventh synchronization control information through the second signal channel 112, where the seventh synchronization control information includes an end signal for the CIM write operation (CIM Pgm End). It should be understood that the fifth period T5 is earlier than the sixth period T6, and the sixth period T6 is earlier than the seventh period T7.

The transmission of the three signal channels in the process of the read/write operation adapted to the ONFI protocol is described below with reference to the accompanying drawings.

In some examples, when performing a second read operation, e.g., when performing the read operation adapted to the ONFI protocol with the semiconductor device, referring to FIG. 2, the control circuit 201 is configured to: send a third command CMD3 through the first signal channel 111, where the third command CMD3 includes a second read instruction and a second read address. The peripheral circuit 102 is configured to: receive and in response to the third command CMD3, send data (such as second read data) stored in the memory array 101 to the control circuit 201 through the first signal channel 111.

In some examples, when performing a second write operation, that is, when performing the write operation adapted to the ONFI protocol with the semiconductor device, referring to FIG. 2, the control circuit 201 is configured to: send a fourth command CMD4 through the first signal channel 111, and the peripheral circuit 102 is configured to: receive and in response to the fourth command CMD4, store the write data included in the fourth command CMD4 in the memory array 101 through the first signal channel 111. To distinguish from the CIM write data, the write data here may be understood as ONFI write data. Similarly, when performing the write verification operation adapted to the ONFI protocol, the ONFI verification data is also transmitted through the first signal channel 111.

In some examples of the present disclosure, when performing a read/write operation adapted to the ONFI protocol, the first signal channel 111 is selected to transmit data or information. When performing the read/write operation of the computing-in-memory CIM, the first signal channel 111, the second signal channel 112, or the third signal channel 113 may be selected for transmission according to different requirements. In this way, the semiconductor device may not only perform a read/write operation adapted to the ONFI protocol, but may also perform a read/write operation of the computing-in-memory CIM, thereby increasing a usage range of the semiconductor device.

In some examples of the present disclosure, the semiconductor device may be implemented as a universal flash memory (UFS) device, a solid state drive (SSD), a multi-media card in the form of a multi-media card (MMC), an embedded MMC (eMMC), an RS-MMC, and a micro MMC, a secure digital (SD) card in the form of a SD, a mini SD, and a micro SD, a Personal Computer Memory Card International Association (PCMCIA) card type of memory device, a peripheral component interconnect (PCI) type of memory device, a PCI-Express (PCI-E) type of memory device, a compact flash memory (CF) card, a smart media card, or a memory stick, and the like. In some examples, the semiconductor device herein may be used on a terminal product such as a computer, a television, a set-top box, a vehicle-mounted device, and the like.

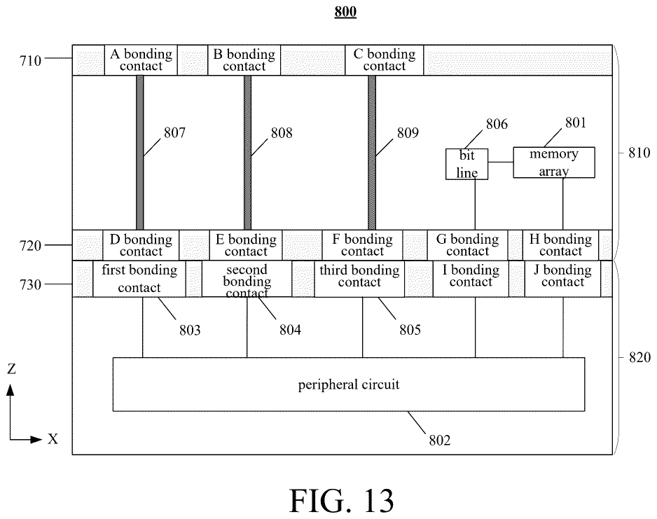

Based on a similar concept to the semiconductor device described above, the present disclosure further provides a semiconductor structure; referring to FIG. 13, the semiconductor structure 800 includes a memory array 801, a peripheral circuit 802 coupled to the memory array 801, a first bonding contact 803, a second bonding contact 804, and a third bonding contact 805 coupled to the peripheral circuit 802, where the first bonding contact 803 is configured to transmit a first signal, the second bonding contact 804 is configured to transmit a second signal, the third bonding contact 805 is configured to transmit a third signal, and information contents of the first signal, the second signal, and the third signal are different.

In some examples, the information content of the first signal includes system information adapted to an ONFI protocol and system information interacted with the peripheral circuit in performing a computing-in-memory process, the information content of the second signal includes synchronization control information interacted with the peripheral circuit in performing the computing-in-memory process, and the information content of the third signal includes system information interacted with the memory array in performing the computing-in-memory process.

In some examples, the semiconductor structure 800 includes a first sub-semiconductor structure 810 formed with a memory array 801 and a second sub-semiconductor structure 820 formed with a peripheral circuit 802, the first sub-semiconductor structure 810 further includes a first bonding layer 710 and a second bonding layer 720 located on two opposite sides of the memory array 801, the second sub-semiconductor structure 820 further includes a third bonding layer 730 formed with a first bonding contact 803, a second bonding contact 804, and a third bonding contact 805, and the second bonding layer 720 is bonded to the third bonding layer 730.

In some examples, the semiconductor structure 800 further includes: a first connection structure 807 through the memory array 801 and connected to the first bonding contact 803, a second connection structure 808 through the memory array 801 and connected to the second bonding contact 804, and a third connection structure 809 through the memory array 801 and connected to the third bonding contact 805.

In some examples, the first bonding layer 710 further includes an A bonding contact, a B bonding contact, and a C bonding contact, the second bonding layer 720 further includes a D bonding contact, an E bonding contact, an F bonding contact, a G bonding contact, and an H bonding contact, the third bonding layer 730 further includes an I bonding contact and a J bonding contact. The A bonding contact is connected to the first bonding contact 803 through the first connection structure 807 and the D bonding contact to form a channel for transmitting the first signal, the B bonding contact is connected to the second bonding contact 804 through the second connection structure 808 and the E bonding contact to form a channel for transmitting the second signal, the C bonding contact is connected to the third bonding contact 805 through the third connection structure 809 and the F bonding contact to form a channel for transmitting the third signal.

In some examples, the semiconductor structure 800 further includes a bit line 806 located between the peripheral circuit 802 and the memory array 801, and the memory array 801 is coupled to the peripheral circuit 802 through the bit line 806.

Based on a similar concept to the semiconductor device described above, the present disclosure further provides a method of manufacturing a semiconductor device, where the method of manufacturing the semiconductor device includes the following operations: forming a first semiconductor structure and a second semiconductor structure bonded to each other, where the first semiconductor structure including a memory array, a peripheral circuit coupled to the memory array, a first bonding contact, a second bonding contact and a third bonding contact respectively coupled to the peripheral circuit, the second semiconductor structure including a control circuit, an analog-to-digital conversion circuit coupled to the control circuit, a fourth bonding contact and a fifth bonding contact respectively coupled to the control circuit, and a sixth bonding contact coupled to the analog-to-digital conversion circuit, where the first bonding contact is coupled to the fourth bonding contact to form a first signal channel, the second bonding contact is coupled to the fifth bonding contact to form a second signal channel, the third bonding contact is coupled to the sixth bonding contact to form a third signal channel, and the first signal channel, the second signal channel, and the third signal channel transmit different information.

In some examples, the first signal channel transmits system information adapted to an ONFI protocol and system information between the control circuit and the peripheral circuit in performing a computing-in-memory process, the second signal channel transmits synchronization control information between the peripheral circuit and the control circuit in performing the computing-in-memory process, and the third signal channel transmits system information between the memory array and the analog-to-digital conversion circuit in performing the computing-in-memory process.

In some examples, the method further includes: forming a bit line between the peripheral circuit and the memory array, and coupling the memory array to the peripheral circuit through the bit line.

In some examples, the forming the first semiconductor structure and the second semiconductor structure bonded to each other includes: forming a memory array and a first bonding layer and a second bonding layer on two opposite sides of the memory array to form a first sub-semiconductor structure; forming the peripheral circuit and a third bonding layer including the first bonding contact, the second bonding contact and the third bonding contact to form a second sub-semiconductor structure; forming the control circuit, the analog-to-digital conversion circuit, and a fourth bonding layer including the fourth bonding contact, the fifth bonding contact and the sixth bonding contact to form a second semiconductor structure; and bonding the fourth bonding layer and the first bonding layer, the second bonding layer, and the third bonding layer to form the first semiconductor structure and the second semiconductor structure bonded to each other.

In some examples, the method further includes: forming a first connection structure through the memory array and connected to the first bonding contact and the fourth bonding contact, respectively; forming a second connection structure through the memory array and connected to the second bonding contact and the fifth bonding contact respectively; and forming a third connection structure through the memory array and connected to the third bonding contact and the sixth bonding contact respectively.

Based on a similar concept to the semiconductor device described above, the present disclosure further provides a method of operating a semiconductor device, where the semiconductor device includes the semiconductor device according to the above examples of the present disclosure, and the method includes: when performing a first read operation, transmitting, by a control circuit, a first command to a peripheral circuit through a first signal channel, where the first command includes a first read instruction, a first read address, and input vector data; in response to the first command, transmitting, by the peripheral circuit, first synchronization control information to the control circuit through a second signal channel, where the first synchronization control information includes a trigger signal for the first read operation to start sensing; instructing, by the control circuit, the analog-to-digital conversion circuit to obtain a first computing-in-memory current signal through a third signal channel, and convert the first computing-in-memory current signal into first read data; transmitting, by the control circuit, second synchronization control information to the peripheral circuit through the second signal channel, where the second synchronization control information includes a trigger signal for sensing completion of the first read operation; and transmitting, by the peripheral circuit, third synchronization control information through the second signal channel, where the third synchronization control information includes an end signal for the first read operation.

In some examples, the method further includes: when performing a write operation, transmitting, by the control circuit, a second command to the peripheral circuit through the first signal channel, where the second command includes write data; and in response to the second command, storing, by the peripheral circuit, the write data in the memory array.

In some examples, the method further includes: when performing a write verification operation, transmitting, by the peripheral circuit, fourth synchronization control information to the control circuit through the second signal channel, where the fourth synchronization control information including state information of the memory array; instructing, by the control circuit, the analog-to-digital conversion circuit to obtain a second computing-in-memory current signal through the third signal channel, and convert the second computing-in-memory current signal into verification data; and verifying with the verification data and the write data, transmitting, by the control circuit, fifth synchronization control information to the peripheral circuit through the second signal channel, where the fifth synchronization control information includes a completion signal for the write verification operation; transmitting, by the peripheral circuit, sixth synchronization control information through the second signal channel, where the sixth synchronization control information includes a signal for storing the verification data to the memory array; transmitting, by the control circuit, the verification data to the peripheral circuit through the third signal channel or the first signal channel; transmitting, by the peripheral circuit, seventh synchronization control information to the control circuit through the second signal channel, where the seventh synchronization control information includes an end signal for the write operation.

In some examples, the method further includes: when performing a second read operation, transmitting, by the control circuit, a third command through the first signal channel, where the third command includes a second read command and a second read address; and in response to the third command, transmitting, by the peripheral circuit, second read data stored in the memory array to the control circuit through the first signal channel.

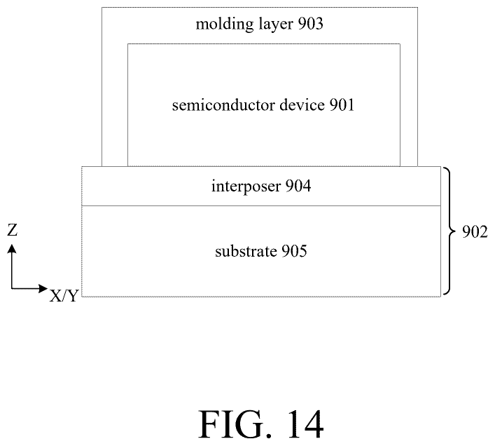

Based on the semiconductor device described above, an example of the present disclosure further provides a package structure, and FIG. 14 is a schematic diagram of a package structure according to an example of the present disclosure, as shown in FIG. 14, the package structure includes: a package substrate 902, the semiconductor device 901 according to the foregoing examples, and a molding layer 903, the semiconductor device 901 is disposed on the package substrate 902, and the molding layer 903 encapsulates the semiconductor device 901.

In some examples, as shown in FIG. 14, the package substrate 902 includes a substrate 905 and an interposer 904 formed on the substrate, a connection circuit is formed in the interposer 904, and the semiconductor device 901 is disposed on a side of the interposer 904 away from the substrate 905.

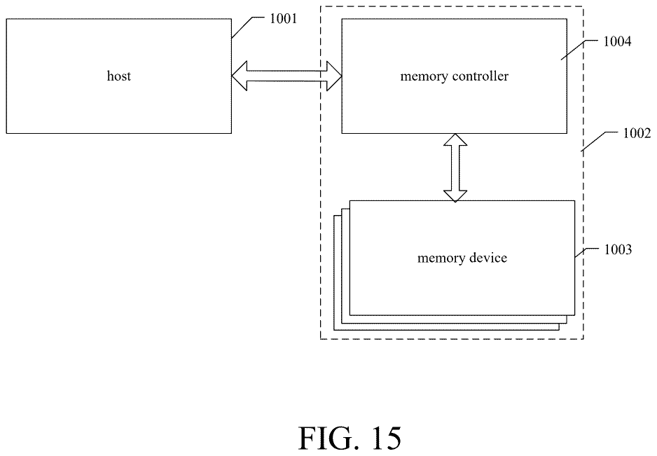

Based on the foregoing semiconductor device, an example of the present disclosure provides a memory device, and FIG. 15 is a schematic diagram of an example of computing-in-memory device having a semiconductor device according to an example of the present disclosure, as shown in FIG. 15, the computing-in-memory device includes a semiconductor device 1002 according to any one of the foregoing examples.

In some examples, as shown in FIG. 15, the computing-in-memory device further includes a host 1001 coupled to the semiconductor device 1002.

In some examples of the present disclosure, the computing-in-memory device may be applied to an electronic device, which may be a mobile phone, a smart phone, a smart watch, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable device having a computing-in-memory device therein. As shown in FIG. 15, the computing-in-memory device may include a host 1001 and a semiconductor device 1002, and the semiconductor device 1002 may include one or more memory devices 1003 and a memory controller 1004. The host 1001 may include a processor of an electronic device, for example, a central processing unit (CPU), or a system on a chip (SoC), for example, an application processor (AP). The host 1001 may be configured to send or receive data to or from the semiconductor device 1002. The memory device 1003 includes a memory array and peripheral circuit coupled to the memory array. The memory device 1003 herein may be the first semiconductor structure in the foregoing examples, and the memory controller 1004 herein may be the second semiconductor structure in the foregoing examples.

In some examples, the memory controller 1004 is coupled to the memory device 1003 and the host 1001 and is configured to control the memory device 1003. The memory controller 1004 may manage data stored in the memory device 1003 and communicate with the host 1001. In some examples, the memory controller 1004 is designed to operate in a low duty cycle environment, such as in a secure digital card, compact flash card (CFC), universal serial bus (USB) flash drive, or other medium for used in electronic devices such as personal computers, digital cameras, mobile phones, and the like. In other examples, the memory controller 1004 is designed to operate in a high duty cycle environment, such as a solid state disk or embedded Multi-Media Card (eMMC).

In some examples, the memory controller 1004 and the one or more memory devices 1003 may be integrated into various types of memory devices, that is, the semiconductor device 1002 may be implemented and packaged into different types of terminal electronics.

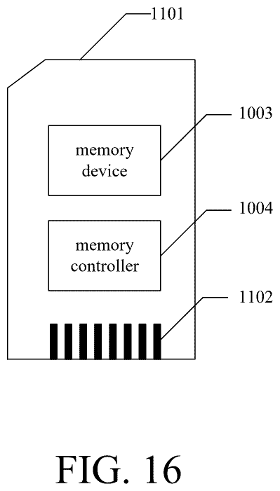

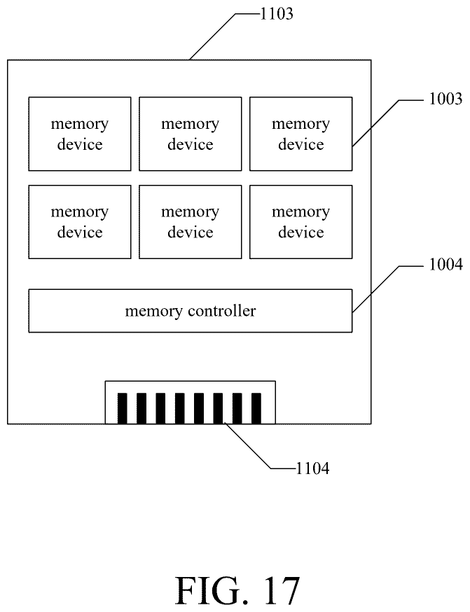

In one example as shown in FIG. 16, the memory controller 1004 and the single memory device 1003 may be integrated into the memory card 1101. The memory card 1101 may be one of a compact flash memory card, a smart media card (SMC), a memory stick (MS), a multi-media card (MMC), for example, an RS-MMC, an MMCmicro, an eMMC, or the like, a secure digital card, for example, a Mini SD card, a Micro SD card, an SDHC card, or the like, and a universal flash memory card. The memory card 1101 may also include a memory card connector 1102 that couples the memory card 1101 with a host-side device (e.g., host 1001 in FIG. 15). In another example as shown in FIG. 17, the memory controller 1004 and the plurality of memory devices 1003 may be integrated into SSD 1103. SSD 1103 may also include an SSD connector 1104 that couples the SSD 1103 with a host-side device (e.g., host 1001 in FIG. 15). In some examples, the memory capacity and/or operating speed of the SSD 1103 is greater than the memory capacity and/or operating speed of memory card 1101.

It should be understood that “some examples” or “some examples of the present disclosure” mentioned throughout the specification means that specific features, structures, or characteristics related to the examples are included in at least one example of the present disclosure. Thus, “in some examples” or “in some examples of the present disclosure” appearing throughout the specification need not necessarily refer to the same example. Further, these particular features, structures, or characteristics may be incorporated in one or more examples in any suitable manner. It should be understood that, in various examples of the present disclosure, the sequence numbers of the above processes do not mean an order of execution sequences, and an execution sequence of each process should be determined by using a function and an intrinsic logic thereof, and should not constitute any limitation on an implementation process of the examples of the present disclosure. The above sequence numbers of the examples of the present disclosure are merely for description, and do not represent the advantages of the examples.

The above description is only a preferred example of the present disclosure, and is not intended to limit the scope of the present disclosure, and under the inventive concept of the present disclosure, any equivalent structural transformation made by using the present disclosure and the accompanying drawings or any direct/indirect application of the present disclosure to other related technical fields is included within the scope of the present disclosure.

What is claimed is:

1. A semiconductor device, comprising:
a first semiconductor structure, comprising:
a memory array;
a peripheral circuit coupled to the memory array; and
a first bonding contact, a second bonding contact, and a third bonding contact respectively coupled to the peripheral circuit,
a second semiconductor structure bonded to the first semiconductor structure, comprising:
a control circuit;
an analog-to-digital conversion circuit coupled to the control circuit;
a fourth bonding contact and a fifth bonding contact respectively coupled to the control circuit; and
a sixth bonding contact coupled to the analog-to-digital conversion circuit, and
wherein a first signal channel is formed between the first bonding contact and the fourth bonding contact, a second signal channel is formed between the second bonding contact and the fifth bonding contact, a third signal channel is formed between the third bonding contact and the sixth bonding contact, and the first signal channel, the second signal channel, and the third signal channel are configured to transmit different information.

2. The semiconductor device of claim 1, wherein
the first signal channel is configured to transmit system information adapted to an open not-and (NAND) flash interface (ONFI) protocol and system information between the control circuit and the peripheral circuit in performing a computing-in-memory process,
the second signal channel is configured to transmit synchronization control information between the peripheral circuit and the control circuit in performing the computing-in-memory process, and
the third signal channel is configured to transmit system information between the memory array and the analog-to-digital conversion circuit in performing the computing-in-memory process.

3. The semiconductor device of claim 2, wherein when performing a first read operation,
the control circuit is configured to send a first command through the first signal channel,
the peripheral circuit is configured to: in response to the first command, send first synchronization control information through the second signal channel, wherein the first synchronization control information comprises a trigger signal for the first read operation to start sensing,
the control circuit is configured to: send a first control signal to the analog-to-digital conversion circuit,
the analog-to-digital conversion circuit is configured to: in response to the first control signal, obtain a first computing-in-memory current signal output by the memory array through the third signal channel; and convert the first computing-in-memory current signal into first read data,
the control circuit is configured to: send second synchronization control information through the second signal channel, wherein the second synchronization control information comprises a trigger signal for sensing completion of the first read operation, and
the peripheral circuit is configured to: send third synchronization control information through the second signal channel, wherein the third synchronization control information comprises an end signal for the first read operation.

4. The semiconductor device of claim 3, wherein
in a first period, the first command is transmitted through the first signal channel,
in a second period, the first synchronization control information is transmitted through the second signal channel, and the first computing-in-memory current signal is transmitted through the third signal channel, wherein the first period is earlier than the second period,
in a third period, the second synchronization control information is transmitted through the second signal channel, wherein the second period is earlier than the third period, and
in a fourth period, the third synchronization control information is transmitted through the second signal channel, wherein the third period is earlier than the fourth period.

5. The semiconductor device of claim 2, wherein when performing a write operation,
the control circuit is configured to: send a second command through the first signal channel, wherein the second command comprises write data, and
the peripheral circuit is configured to: in response to the second command, store the write data to the memory array.

6. The semiconductor device of claim 5, wherein when performing a write verification operation,
the peripheral circuit is configured to: send fourth synchronization control information through the second signal channel, wherein the fourth synchronization control information comprises state information of the memory array,
the control circuit is configured to: send a second control signal to the analog-to-digital conversion circuit,
the analog-to-digital conversion circuit is configured to: in response to the second control signal, obtain a second computing-in-memory current signal output by the memory array through the third signal channel; and convert the second computing-in-memory current signal into verification data,
the control circuit is configured to: verify with the write data and the verification data, and send fifth synchronization control information through the second signal channel, wherein the fifth synchronization control information comprises a completion signal for a verification operation,
the peripheral circuit is configured to: send sixth synchronization control information through the second signal channel, wherein the sixth synchronization control information comprises a signal for storing the verification data to the memory array,
the control circuit is configured to: send a third control signal to the analog-to-digital conversion circuit, the analog-to-digital conversion circuit is configured to: in response to the third control signal, store the verification data to the memory array through the third signal channel, or the control circuit is configured to: store the verification data to the memory array through the first signal channel, and
the peripheral circuit is configured to: send seventh synchronization control information through the second signal channel, wherein the seventh synchronization control information comprises an end signal for the write operation.

7. The semiconductor device of claim 6, wherein
in a fifth period, the second command is transmitted through the first signal channel,
in a sixth period, the fourth synchronization control information is transmitted through the second signal channel, the second computing-in-memory current signal is transmitted through the third signal channel, the fifth synchronization control information and the sixth synchronization control information are respectively transmitted through the second signal channel, the verification data is transmitted through the third signal channel or the first signal channel, wherein the fifth period is earlier than the sixth period, and
in a seventh period, the seventh synchronization control information is transmitted through the second signal channel, wherein the sixth period is earlier than the seventh period.

8. The semiconductor device of claim 1, wherein when performing a second read operation,
the control circuit is configured to: send a third command through the first signal channel, and
the peripheral circuit is configured to: in response to the third command, send second read data stored in the memory array to the control circuit through the first signal channel.

9. The semiconductor device of claim 1, wherein the first semiconductor structure further comprises a bit line located between the peripheral circuit and the memory array, and the memory array is coupled to the peripheral circuit through the bit line.

10. The semiconductor device of claim 1, wherein the first semiconductor structure comprises:
a first sub-semiconductor structure formed with the memory array, wherein the first sub-semiconductor structure further comprises a first bonding layer and a second bonding layer located on two opposite sides of the memory array; and
a second sub-semiconductor structure formed with the peripheral circuit, wherein the second sub-semiconductor structure further comprises:
a third bonding layer formed with the first bonding contact, the second bonding contact and the third bonding contact; and
a fourth bonding layer formed with the fourth bonding contact, the fifth bonding contact and the sixth bonding contact, and wherein
the fourth bonding layer is bonded to the first bonding layer, and the second bonding layer is bonded to the third bonding layer.

11. The semiconductor device of claim 10, wherein the semiconductor device further comprises:
a first connection structure through the memory array and connected to the first bonding contact and the fourth bonding contact respectively;
a second connection structure through the memory array and connected to the second bonding contact and the fifth bonding contact respectively; and
a third connection structure through the memory array and connected to the third bonding contact and the sixth bonding contact respectively.

12. The semiconductor device of claim 1, wherein the second semiconductor structure comprises a three-dimensional not-and (NAND) type memory.

13. A semiconductor structure, comprising:
a memory array;
a peripheral circuit coupled to the memory array; and
a first bonding contact, a second bonding contact, and a third bonding contact respectively coupled to the peripheral circuit,
wherein the first bonding contact is configured to transmit a first signal, the second bonding contact is configured to transmit a second signal, and the third bonding contact is configured to transmit a third signal, and wherein information contents of the first signal, the second signal, and the third signal are different.

14. The semiconductor structure of claim 13, wherein
information content of the first signal comprises system information adapted to an open not-and (NAND) flash interface (ONFI) protocol and system information interacted with the peripheral circuit in performing a computing-in-memory process,
information content of the second signal comprises synchronization control information interacted with the peripheral circuit in performing the computing-in-memory process, and
information content of the third signal comprises system information interacted with the memory array in performing the computing-in-memory process.

15. The semiconductor structure of claim 13, comprising:
a first sub-semiconductor structure formed with the memory array, wherein the first sub-semiconductor structure further comprises a first bonding layer and a second bonding layer located on two opposite sides of the memory array; and
a second sub-semiconductor structure formed with the peripheral circuit, wherein the second sub-semiconductor structure further comprises a third bonding layer formed with the first bonding contact, the second bonding contact and the third bonding contact, and wherein the second bonding layer is bonded to the third bonding layer.

16. The semiconductor structure of claim 15, further comprising:
a first connection structure through the memory array and connected to the first bonding contact;
a second connection structure through the memory array and connected to the second bonding contact; and
a third connection structure through the memory array and connected to the third bonding contact.

17. A method of operating a semiconductor device, comprising:
during performing a first read operation, transmitting, by a control circuit, a first command to a peripheral circuit through a first signal channel, wherein the first command comprises a first read instruction, a first read address, and input vector data;
in response to the first command, transmitting, by the peripheral circuit, first synchronization control information to the control circuit through a second signal channel, wherein the first synchronization control information comprises a trigger signal for the first read operation to start sensing;
instructing, by the control circuit, an analog-to-digital conversion circuit to obtain a first computing-in-memory current signal through a third signal channel, and convert the first computing-in-memory current signal into first read data;
transmitting, by the control circuit, second synchronization control information to the peripheral circuit through the second signal channel, wherein the second synchronization control information comprises a trigger signal for sensing completion of the first read operation; and
transmitting, by the peripheral circuit, third synchronization control information through the second signal channel, wherein the third synchronization control information comprises an end signal for the first read operation.

18. The method of claim 17, further comprising:
during performing a write operation, transmitting, by the control circuit, a second command to the peripheral circuit through the first signal channel, wherein the second command comprises write data; and
in response to the second command, storing, by the peripheral circuit, the write data to a memory array.

19. The method of claim 18, further comprising: during performing a write verification operation,
transmitting, by the peripheral circuit, fourth synchronization control information to the control circuit through the second signal channel, wherein the fourth synchronization control information comprises state information of the memory array;
instructing, by the control circuit, the analog-to-digital conversion circuit to obtain a second computing-in-memory current signal through the third signal channel, and convert the second computing-in-memory current signal into verification data; and verifying with the write data and the verification data;
transmitting, by the control circuit, fifth synchronization control information to the peripheral circuit through the second signal channel, wherein the fifth synchronization control information comprises a completion signal for the write verification operation;
transmitting, by the peripheral circuit, sixth synchronization control information through the second signal channel, wherein the sixth synchronization control information comprises a signal for storing the verification data to the memory array;
transmitting, by the control circuit, the verification data to the peripheral circuit through the third signal channel or the first signal channel; and
transmitting, by the peripheral circuit, seventh synchronization control information to the control circuit through the second signal channel, wherein the seventh synchronization control information comprises an end signal for the write operation.

20. The method of claim 17, further comprising: during performing a second read operation,
transmitting, by the control circuit, a third command through the first signal channel, wherein the third command comprises a second read command and a second read address; and
in response to the third command, transmitting, by the peripheral circuit, second read data stored in the memory array to the control circuit through the first signal channel.
